(19) United States
(12) Patent Application Publication
(10) Pub. No.: US 2025/0224436 A1
(43) Pub. Date: Jul. 10, 2025

(54) METHOD FOR TRACING POWER SUPPLY PATHS IN IMPORTANT LOCATIONS BASED ON DIGITAL TWINS

(71) Applicant: STATE GRID ZHEJIANG TONGXIANG ELECTRIC POWER SUPPLY COMPANY, Zhejiang (CN)

(72) Inventors: Guangzeng WANG, Zhejiang (CN); Jianliang FANG, Zhejiang (CN); Guangzhen REN, Zhejiang (CN); Guoliang Liu, Zhejiang (CN); Hong Xu, Zhejiang (CN); Haiqiang YAO, Zhejiang (CN); Tiantian GU, Zhejiang (CN); Shuhan LIU, Zhejiang (CN)

(73) Assignee: STATE GRID ZHEJIANG TONGXIANG ELECTRIC POWER SUPPLY COMPANY, Zhejiang (CN)

(21) Appl. No.: 18/681,518

(22) PCT Filed: Dec. 26, 2023
(86) PCT No.: PCT/CN2023/141781

§ 371 Date: Feb. 6, 2024

(30) Foreign Application Priority Data
Dec. 20, 2023 (CN) 202311771481.1

(51) Int. Cl. G01R 31/08

(52) U.S. Cl. CPC G01R 31/086

(57) ABSTRACT

The present invention discloses a method for tracing power supply paths in important locations based on digital twins. In order to solve the problem that it is time-consuming and laborious in the prior art due to the fact of requiring manual data collection and mapping in the case where the mapping of a single object in a digital space needs to be restored according to the actual situation on the spot, the present invention hierarchically establishes digital twin scenarios, constructs a complete power supply path according to a signal flow relationship between power topology and equipment, and conducts power supply path tracing in the event of equipment failure to determine a scope of influence, thus being fast and accurate in tracing.

### TECHNICAL FIELD

The present invention relates to the field of power supply path tracing, and in particular to a method for tracing power supply paths in important locations based on digital twins.

### BACKGROUND ART

In view of the power maintenance command work of major events, the traditional venue power supply path traceability guarantee dimension coverage is not insufficient, the equipment status monitoring range is not comprehensive enough, the control implementation and supervision of power maintenance patrol watch and rush repair task as well as the effectiveness of on-site penetration command need to be improved.

The conventional twin construction of venues mostly employs an agile development model with actual on-site demands as a core, while the on-site modeling demand is often achieved by collecting manually and with the help of equipment, and the details are judged by human eyes and experience values. When the mapping of a single object in a digital space is restored according to the actual situation on the spot, there is a lack of linkage display between equipment; and if some equipment encounters abnormalities, it is difficult to determine the nodes causing the failure and the fault impact scope by tracing the power supply paths corresponding to the abnormal equipment. For example, a “Digital Twinning System for Power Plant” disclosed in the Chinese patent document with Publication No. of CN114926603A includes: a three-dimensional scenario layer, used for performing forward three-dimensional design and reverse three-dimensional design on a power plant to build a digital power plant; a digital twin implementation layer, used for performing three-dimensional element extraction on the digital power plant, establishing a mapping relationship between three-dimensional elements and codes of a power plant identification system, configuring a logical relationship between the three-dimensional elements with the established mapping relationship, and coupling the three-dimensional elements with multi-source data of the power plant according to the mapping relationship and the logical relationship to build a digital twin power plant; and a display layer, where the display layer is interactively connected with the digital twin implementation layer and is used to render and display the digital twin power plant. This solution needs to restore the mapping of a single object in a digital space according to the actual situation on the spot, which requires manual data collection and mapping, thus being time-consuming and laborious, and lacking linkage between equipment.

### SUMMARY OF THE INVENTION

The present invention mainly solves the problem that it is time-consuming and laborious in the prior art due to the fact of requiring manual data collection and mapping in the case where the mapping of a single object in a digital space needs to be restored according to the actual situation on the spot. Provided is a method for tracing power supply paths in important locations based on digital twins, which hierarchically establishes digital twin scenarios, constructs a complete power supply path according to a signal flow relationship between power topology and equipment, and conducts power supply path tracing in the event of equipment failure to determine a scope of influence, thus being fast and accurate in tracing.

The present invention solves the above-mentioned technical problem mainly through the following technical solution:

A method for tracing power supply paths in important locations based on digital twins includes the following steps:
S1: hierarchically establishing, according to actual regional scenarios, a two-dimensional digital twin scenario and a three-dimensional digital twin scenario which correspond to each other;
S2: acquiring equipment information including IP addresses uploaded by all network distribution equipment, from control centers in the corresponding areas; and assigning, according to the monitored equipment information, the network distribution equipment to corresponding spatial positions in the two-dimensional digital twin scenario and the three-dimensional digital twin scenario;
S3: connecting, according to an existing topology diagram, all the network distribution equipment to form preliminary power supply paths, controlling the network distribution equipment to send marking commands to upstream network distribution equipment respectively, allowing the network distribution equipment to send feedback on markers to control centers, and optimizing and correcting the preliminary power supply paths, so as to form a plurality of equipment power supply paths; and
S4: when there is an abnormality in the network distribution equipment, tracing according to the power supply path where the network distribution equipment is located, so as to determine a faulty path and faulty equipment.

In this solution, the digital twin scenarios are hierarchically established, a complete power supply path is constructed according to the signal flow relationship between the power topology and the equipment, and power supply path tracing is conducted in the event of equipment failure to determine the scope of influence, so that tracing is fast and accurate.

Preferably, the two-dimensional digital twin scenario is a two-dimensional regional scenario; and the two-dimensional regional scenario includes relative positions of various locations within a region, and the corresponding network distribution equipment in various locations; and
the three-dimensional digital twin scenario is a three-dimensional location scenario; and the three-dimensional location scenario includes spatial position distribution of the corresponding network distribution equipment in various locations.

The digital twin scenarios are hierarchically established respectively from the perspective of the macro regional scenario and the specific location scenario, which can macroscopically supervise the power supply relationship of various power supply paths within a region, and also provide targeted information supervision for the network distribution equipment in all the scenarios. The locations include switch stations, power distribution rooms, venues, box transformers, etc.

Preferably, step S2 includes the following process:
S201: acquiring the equipment information uploaded by the network distribution equipment from control centers in the areas, where the monitored equipment information includes IP addresses, types, models, numbers, and index parameters (e.g., on and off states of switches, current values of ammeters, etc.) of the corresponding types;
S202: assigning, according to IP addresses in the equipment information of the network distribution equipment, the network distribution equipment to corresponding locations in the two-dimensional digital scenario;
S203: matching, according to equipment types and numbers in the equipment information, the network distribution equipment in various locations with the network distribution equipment in the three-dimensional digital scenario, so as to match the equipment information to corresponding spatial positions.

The digital twin scenarios are hierarchically established respectively from the perspective of the macro regional scenario and the specific location scenario, which can macroscopically supervise the power supply relationship of various power supply paths within a region, and also provide targeted information supervision for the network distribution equipment in all the scenarios.

Preferably, step S3 includes the following process:
S301: acquiring a corresponding network distribution topology diagram within a region from control centers in the areas, and connecting, according to the network distribution topology diagram, all the network distribution equipment in the digital scenarios to obtain the preliminary power supply paths;
S302: acquiring all the terminal network distribution equipment in the preliminary power supply paths, controlling all the network distribution equipment to send the marking commands to the upstream network distribution equipment respectively, and allowing the network distribution equipment to send the feedback on the markers to control centers upon receiving the marking commands;
S303: instructing control centers to collect the feedback on the markers sent by all the network distribution equipment, and forming, according to a content of the feedback on the markers, topological connection relationships between distribution networks;
S304: comparing the topological connection relationships of the feedback on the markers with the network distribution topology diagram, and optimizing and supplementing the preliminary power supply paths, so as to form the plurality of equipment power supply paths.

Combined with the existing topology diagram and the topological connection relationship of information flow feedback, the power supply paths are ensured to be accurate.

Preferably, the marking commands include markers whose names contain unique numbers of the terminal network distribution equipment; and an initial value of the marking commands is 0;
the expression for the command markers is: flag (X), where X is the unique numbers of the terminal network distribution equipment;
after receiving command markers sent by downstream network distribution equipment, the network distribution equipment adds one to the values of the command markers to obtain corresponding feedback on the markers;
the feedback on the markers includes the markers whose names contain unique numbers of the corresponding terminal network distribution equipment and unique codes of the network distribution equipment that send the command markers;
the expression for the feedback on the markers is: flag (X_Y), where Y is the unique numbers of the network distribution equipment that send the command markers; and
the network distribution equipment forms a set of all feedback on the markers, and sends same to control centers.

Preferably, a transmission method of command markers is as follows:
instructing the terminal network distribution equipment to send the command markers with an initial value of 0 to the upstream network distribution equipment;
for the network distribution equipment that have received the command markers, adding one to the command markers to form feedback on the markers, and transmitting the command markers after adding one to the values to the remaining network distribution equipment connected to the above network distribution equipment, where the command markers are not sent to the remaining network distribution equipment; and
transmitting the command markers circularly until there is no object to which the command markers can be transmitted in all the network distribution equipment.

Through the transmission of information flow, the connection relationships between the network distribution equipment are determined, which is used to improve the topology diagram and ensure the reliability of the power supply paths.

Preferably, control centers in the areas will be classified according to an expression of the feedback on the markers, and arranged in a descending order of values; and a plurality of groups of topological connection relationships are obtained;
all the topological connection relationships are traversed to determine whether there are same topological connection relationships in the preliminary power supply paths; if so, the corresponding topological connection relationships are removed; and otherwise, a next step of conflict resolution is proceeded; and
whether the topological connection relationships conflict with the existing preliminary power supply paths is determined; if so, the corresponding topological connection relationships are removed; and otherwise, the equipment power supply paths are formed according to the topological connection relationships.

Preferably, step S4 includes the following process:
S401: performing real-time collection and acquisition on the equipment information uploaded by all the network distribution equipment, and comparing index parameters in the equipment information with corresponding threshold values, so as to determine whether the network distribution equipment is abnormal;
S402: when there is an abnormality in the network distribution equipment, tracing upstream according to the equipment power supply path, and determining a faulty power supply node based on statuses of the network distribution equipment at all power supply nodes in the equipment power supply paths;
S403: determining, according to all the equipment power supply paths associated with the faulty power supply node, a fault impact scope, and locating a spatial position of the faulty equipment to perform a power maintenance operation.

The visual display of the scope of influence caused by equipment failure provides clear and intuitive guidance for logistics power supply support.

Preferably, the process of tracing upstream specifically includes:
1) if there is only one abnormal power supply path in the same time period, the most upstream power supply node, at which the abnormal equipment exists, in the power supply path is determined as a faulty power supply node;
2) if there is more than one abnormal power supply path in the same time period, it is determined whether the same power supply nodes exist in the abnormal power supply paths;
if there are no same power supply nodes in the abnormal power supply paths, the upstream power supply nodes, at which the abnormal equipment exist, in the power supply paths are determined as the faulty power supply nodes, respectively;
if the same power supply nodes exist in the abnormal power supply paths, the same power supply nodes in the paths are extracted, and the equipment information of the abnormal equipment at the corresponding power supply nodes is fed back;
3) whether the abnormal equipment at the same power supply nodes in all the power supply paths are the same is determined; if so, the same abnormal equipment is extracted and determined as the abnormal equipment; and otherwise, each abnormal equipment is checked respectively, and a most upstream abnormal equipment in the power supply path is treated as the faulty equipment.

All the power supply paths are traced upstream simultaneously, and the fault locations are rapidly determined through the common fault nodes, which makes determination more intuitive, is conducive to the determination of emergency fault at an important moment, and accelerates the scheduling speed of subsequent maintenance.

Preferably, the faulty power supply nodes and the fault impact scope of the faulty paths are shown in the two-dimensional digital scenario; and positions of the faulty equipment are shown in the three-dimensional digital scenario.

The visual display of the scope of influence caused by equipment failure and the specific locations of the faulty equipment provide clear and intuitive guidance for logistics power supply support.

The present invention has the following beneficial effects.
1. The digital twin scenarios are hierarchically established respectively from the perspective of the macro regional scenario and the specific location scenario, which can macroscopically supervise the power supply relationship of various power supply paths within a region, and also provide targeted information supervision for the network distribution equipment in all the scenarios.
2. The complete power supply path is constructed according to the signal flow relationship between the power topology and the equipment, and power supply path tracing is conducted in the event of equipment failure to determine the scope of influence, so that tracing is fast and accurate.
3. All the power supply paths are traced upstream simultaneously, and the fault locations are rapidly determined through the common fault nodes, which makes determination more intuitive, is conducive to the determination of emergency fault at an important moment, and accelerates the scheduling speed of subsequent maintenance.
4. The visual display of the scope of influence caused by equipment failure and the specific locations of the faulty equipment provide clear and intuitive guidance for logistics power supply support.

### BRIEF DESCRIPTION OF THE DRAWINGS

FIG. 1 is a flow chart of a method for tracing power supply paths in important locations based on digital twins according to the present invention.

FIG. 2 is a flow chart showing power supply path construction according to the present invention.

FIG. 3 is a flow chart showing tracing upstream according to the present invention.

### DETAILED DESCRIPTION OF THE INVENTION

The technical solution of the present invention will be further described in detail below through embodiments and in conjunction with the accompanying drawings.

### Embodiment I

A method for tracing power supply paths in important locations based on digital twins in this embodiment can be applied to power maintenance locations of several conference venues such as integrated conference theme pavilions, conference exhibition halls and report halls. Microservice-oriented architecture design is employed. Based on the infrastructure of an integrated cloud platform, new business applications are added using the IaaS and PaaS capability components of the integrated cloud platform, and cloud deployment is carried out by means of node virtualization. The application scenarios and capabilities of the components are as follow:

### (1) Infrastructure Layer

An infrastructure layer provides general computing, memory, and network services. The computing service provides new business applications added based on computing environments such as virtual machines. The memory service supports data storage methods such as relational database storage, object storage, and file storage. A system bus provides a message queue. The network service provides dedicated network VPC, load balancing, virtual firewall and other capabilities.

### (2) Data Layer

User-side power distribution monitoring and analysis applications are based on the integrated scheduling graphics, models and data of a business central console, network configuration, as well as the graphics, models and data for user-side network configuration. Hot spot data is cached in a memory by using a cache database technology, which can greatly reduce the reading pressure on the central console.

### (3) Service Layer

In order to improve performance, the service layer internally applies RPC or Restful protocols for mutual invocation, and services are registered and discovered through a unified registration center for effective service management.

A system provides real-time data integration services, graph and model access and verification services in response to a central console, and provides real-time data release services and alarm services externally. Based on a message queue, the functions such as message conversion (conversion, enrichment, filtering), and message routing (synchronous/asynchronous, publish/subscribe, content-based routing, branching and aggregation) are completed to ensure the accuracy and timeliness of data integration.

The back-end application adopts microservice-oriented architecture design. The service governance and security management functions are provided by a cloud platform in a unified manner. API gateway is the only entry point for external service calls of a microservice system, and all clients and consumers access microservices through the unified gateway. Service governance and security management are provided by the cloud platform in a unified manner, following the principle of giving priority to components of the cloud platform, so as to ensure the stable and safe operation of services.

### (4) Business Application Layer

A front-end presentation layer adopts a front-end framework, combined with front-end generic components, so as to build application pages. The application pages for network distribution panoramic monitoring, fault alarm monitoring, and user panoramic monitoring are provided. Based on digital twins, the monitoring of basic data and real-time data such as power maintenance venues, substations, power transmission lines, power distribution equipment, monitoring devices, security resources, fault alarms, risk hidden dangers, inspection and repair tasks, weather scale, and geographical distribution is realized, the panoramic monitoring display is carried out by using the linkage of statistical chart, detailed lists, and three-dimensional simulation applications, and thus abnormalities are found in time, which facilitates a comprehensive understanding of the latest developments in tracing of low-voltage power supply paths of current holding objects. Moreover, the release and monitoring of various types of auxiliary information such as global meteorological monitoring, life cycle management of power equipment, three-dimensional visualization of fault alarms, and spectaculars of alarm historical activities are carried out.

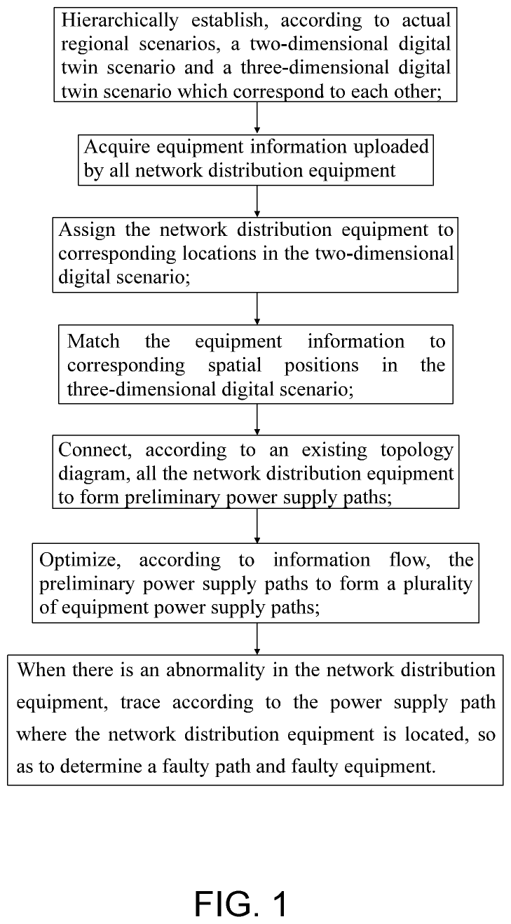

Specifically, this embodiment provides a method for tracing power supply paths in important locations based on digital twins as shown in FIG. 1, which includes the following steps:

S1: Hierarchically establishing, according to actual regional scenarios, a two-dimensional digital twin scenario and a three-dimensional digital twin scenario which correspond to each other.

In this embodiment, the two-dimensional digital twin scenario is a two-dimensional regional scenario.

The two-dimensional regional scenario includes relative positions of various locations within a region and corresponding network distribution equipment in various locations. That is, on the two-dimensional map of a regional scope where the important locations that require power maintenance are located, the corresponding power supply related locations (such as conference venues, switching stations, power distribution rooms, and substations) that need attention are displayed at the corresponding positions on the map by marking and rendering. The relative positional relationships between the locations can be expressed.

Based on a geographic information system, real-time visual monitoring is performed on key areas, the locations, statuses, key indexes and other information of the key areas can be analyzed in a manner of linkage, labeled and displayed, and the real-time situation of the key areas can be comprehensively monitored. Guarantee lines are capable of handling according to different voltage levels and classifications during actual operation.

In this embodiment, the three-dimensional digital twin scenario is a three-dimensional location scenario.

The three-dimensional location scenario includes the spatial position distribution of the corresponding network distribution equipment in various locations. The mentioned locations include switching stations, power distribution rooms, venues, box transformers, etc. That is, three-dimensional locations are constructed in the corresponding locations. For example, for a power distribution room, a site is constructed according to the actual location of the power distribution room, and corresponding equipment cabinets and circuit layouts are laid out at the corresponding positions, thus completing the three-dimensional digital twin of a power distribution room scenario.

As for the modeling of supporting distribution station buildings related to power maintenance locations, the modeling scope includes building structures, primary equipment, key secondary equipment and auxiliary control equipment. The modeling hierarchy granularity reaches a level L3, and the production of DTID labels is completed. The modeling work and data matching of relevant pole and tower lines and station buildings are carried out on venue power supply paths, completing the two-dimensional and three-dimensional linkage matching of the power supply paths. The guarantee levels and voltage classification information of all guarantee lines are displayed, which realizes the optimized classification of the chart effects of all the guarantee lines; and the relevant chart information is displayed according to different guarantee levels at a station terminal, including the basic information of the station terminal, electricity load and other chart displays, as well as the effect of primary wiring diagrams.

The digital twin scenarios are hierarchically established respectively from the perspective of the macro regional scenario and the specific location scenario, which can macroscopically supervise the power supply relationship of various power supply paths within a region, and also provide targeted information supervision for the network distribution equipment in all the scenarios.

S2: Acquiring equipment information including IP addresses uploaded by all network distribution equipment, from control centers in the corresponding areas; and assigning, according to the monitored equipment information, the network distribution equipment to corresponding spatial positions in the two-dimensional digital twin scenario and the three-dimensional digital twin scenario.

S201: Acquiring the equipment information uploaded by the network distribution equipment from control centers in the areas.

The monitored equipment information includes IP addresses, types, models, numbers, and index parameters (e.g., on and off states of switches, current values of ammeters, etc.) of the corresponding types.

The system supports viewing of distribution station buildings, network distribution lines and network distribution equipment, as well as basic information such as voltage levels, owned feeder lines, owned plant stations, real-time remote signaling and telemetry. The system supports monitoring the power supply topology of the network configuration based on a primary single-line diagram to display the live status of power distribution equipment. The operating statuses of integrated user-side switching stations, internal power distribution rooms, internal box transformer electrical equipment, venue temporary electrical equipment, and the like include online monitoring data.

S202: Assigning, according to IP addresses in the equipment information of the network distribution equipment, the network distribution equipment to corresponding locations in the two-dimensional digital scenario.

All sites correspond to different IP addresses, and it is determined which site the corresponding data belongs to according to the IP address uploaded by the network distribution equipment.

S203: Matching, according to equipment types and numbers in the equipment information, the network distribution equipment in various locations with the network distribution equipment in the three-dimensional digital scenario, so as to match the equipment information to corresponding spatial positions.

Each equipment has its own unique code. According to the type and number of the network distribution equipment, the corresponding equipment data can be matched to the corresponding actual spatial location according to the location of field investigation or the scene picture information acquired by a camera.

S3: Connecting, according to an existing topology diagram, all the network distribution equipment to form preliminary power supply paths, controlling the network distribution equipment to send marking commands to upstream network distribution equipment respectively, allowing the network distribution equipment to send feedback on markers to control centers, and optimizing and correcting the preliminary power supply paths, so as to form a plurality of equipment power supply paths.

S301: Acquiring a corresponding network distribution topology diagram within a region from control centers in the areas, and connecting, according to the network distribution topology diagram, all the network distribution equipment in the digital scenarios to obtain the preliminary power supply paths.

In the control center of the area, there is generally a power topology diagram of the corresponding area stored. According to the stored power topology diagram, each of various locations in the constructed two-dimensional digital scenario is treated as a node for connection, forming the plurality of preliminary power supply paths.

Further, for each location, according to the power topology diagrams, all the power supply paths are detailed, and all the equipment in the locations are connected, so that the preliminary power supply paths are perfected.

S302: Acquiring all the terminal network distribution equipment in the preliminary power supply paths, controlling all the network distribution equipment to send the marking commands to the upstream network distribution equipment respectively, and allowing the network distribution equipment to send the feedback on the markers to control centers upon receiving the marking commands.

The marking commands include the markers whose names contain unique numbers of the terminal network distribution equipment; and an initial value of the marking commands is 0. In this embodiment, the expression for the command markers is: flag (X), where X is the unique numbers of the terminal network distribution equipment.

After receiving command markers sent by downstream network distribution equipment, the network distribution equipment adds one to the values of the command markers to obtain corresponding feedback on the markers; and the feedback on the markers includes the markers whose names contain unique numbers of the corresponding terminal network distribution equipment and unique codes of the network distribution equipment that send the command markers.

The expression for the feedback on the markers is: flag (X_Y), where Y is the unique numbers of the network distribution equipment that send the command markers.

That is, flag (X_Y)=flag (X)+1.

The network distribution equipment forms a set of all feedback on the markers, and sends same to control centers.

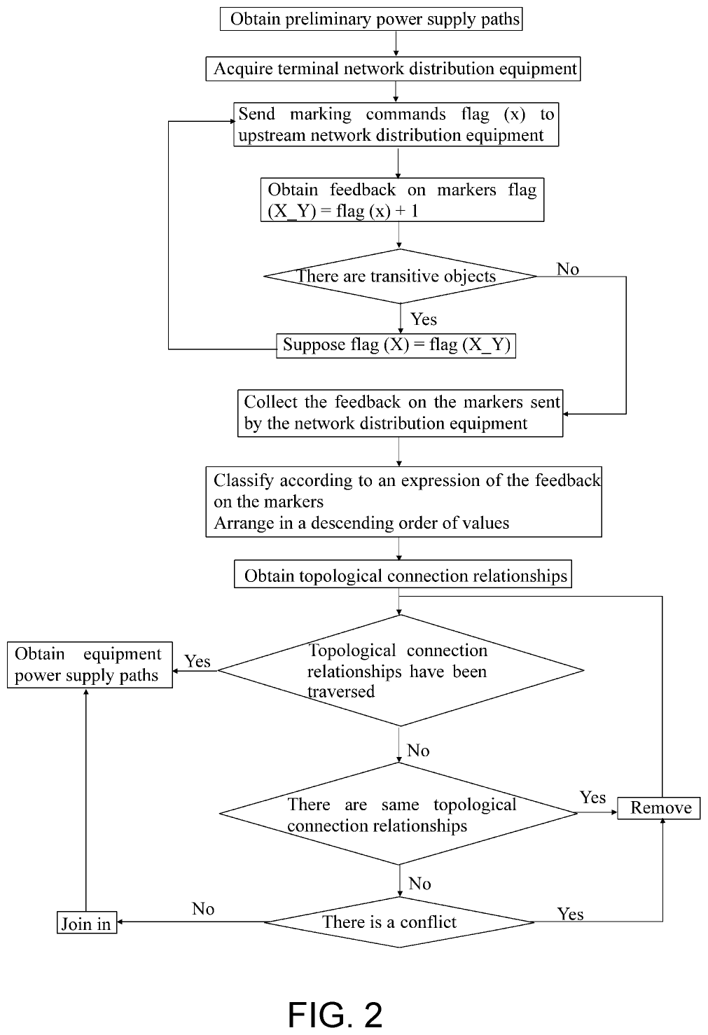

As shown in FIG. 2, a transmission method of command markers is as follows:
1) Instructing the terminal network distribution equipment to send the command markers with an initial value of 0 to the upstream network distribution equipment.
2) For the network distribution equipment that have received the command markers, adding one to the command markers to form feedback on the markers, and transmitting the command markers after adding one to the values to the remaining network distribution equipment connected to the above network distribution equipment, where the command markers are not sent to the remaining network distribution equipment.
3) Transmitting the command markers circularly until there is no object to which the command markers can be transmitted in all the network distribution equipment.

Through the transmission of information flow, the connection relationships between the network distribution equipment are determined, which is used to improve the topology diagram and ensure the reliability of the power supply paths.

S303: Instructing control centers to collect the feedback on the markers sent by all the network distribution equipment, and forming, according to a content of the feedback on the markers, topological connection relationships between distribution networks.

Control centers in the areas will be classified according to an expression of the feedback on the markers, and arranged in a descending order of values; and a plurality of groups of topological connection relationships are obtained.

The feedback on the markers with the unique codes X for the same terminal equipment is classified into one category; and for the network distribution equipment with the same values in the same category, connection objects are determined according to the network distribution equipment Y that sends the command markers, so as to obtain the corresponding topological connection relationships.

S304: Comparing the topological connection relationships of the feedback on the markers with the network distribution topology diagram, and optimizing and supplementing the preliminary power supply paths, so as to form the plurality of equipment power supply paths.

All the topological connection relationships are traversed to determine whether there are same topological connection relationships in the preliminary power supply path; if so, the corresponding topological connection relationships are removed; and otherwise, a next step of conflict resolution is proceeded.

Whether the topological connection relationships conflict with the existing preliminary power supply path is determined; if so, the corresponding topological connection relationships are removed; and otherwise, the equipment power supply paths are formed according to the topological connection relationships.

S4: When there is an abnormality in the network distribution equipment, tracing according to the power supply path where the network distribution equipment is located, so as to determine a faulty path and faulty equipment.

S401: Performing real-time collection and acquisition on the equipment information uploaded by all the network distribution equipment, and comparing index parameters in the equipment information with corresponding threshold values, so as to determine whether the network distribution equipment is abnormal.

S402: When there is an abnormality in the network distribution equipment, tracing upstream according to the equipment power supply path, and determining a faulty power supply node based on statuses of the network distribution equipment at all power supply nodes in the equipment power supply paths.

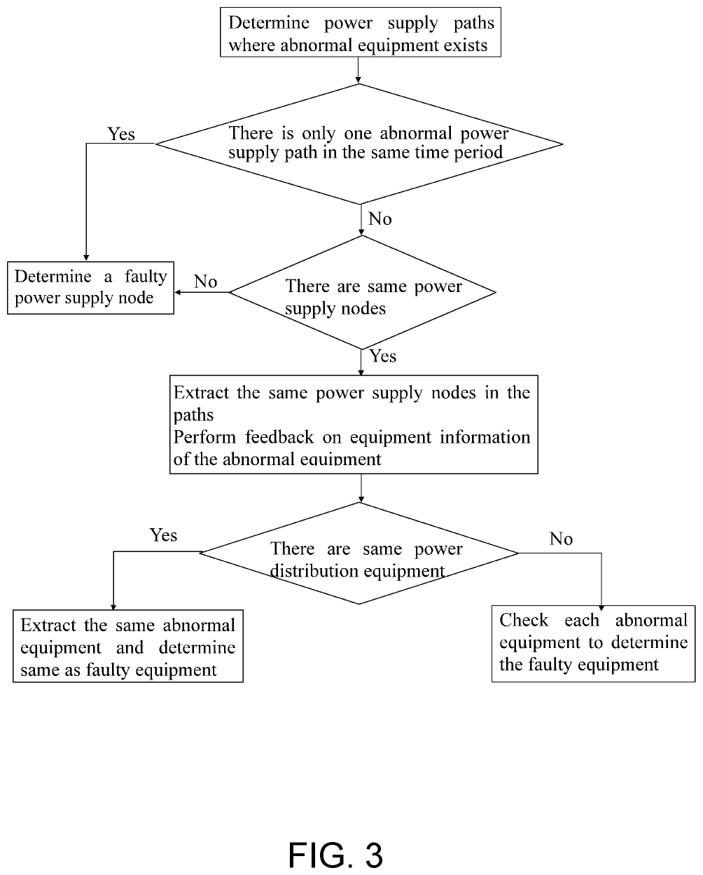

As shown in FIG. 3, the process of tracing upstream according to the equipment power supply paths is as follows:
1) if there is only one abnormal power supply path in the same time period, the most upstream power supply node, at which the abnormal equipment exists, in the power supply path is determined as a faulty power supply node;
2) if there is more than one abnormal power supply path in the same time period, it is determined whether the same power supply nodes exist in the abnormal power supply paths;
if there are no same power supply nodes in the abnormal power supply paths, the upstream power supply nodes, at which the abnormal equipment exist, in the power supply paths are determined as the faulty power supply nodes, respectively;
if the same power supply nodes exist in the abnormal power supply paths, the same power supply nodes in the paths are extracted, and the equipment information of the abnormal equipment at the corresponding power supply nodes is fed back.

S403: Determining, according to all the equipment power supply paths associated with the faulty power supply node, a fault impact scope, and locating a spatial position of the faulty equipment to perform a power maintenance operation.

Whether the abnormal equipment at the same power supply nodes in all the power supply paths are the same is determined; if so, the same abnormal equipment is extracted and determined as the abnormal equipment; and otherwise, each abnormal equipment is checked respectively, and a most upstream abnormal equipment in the power supply path is treated as the faulty equipment.

All the power supply paths are traced upstream simultaneously, and the fault locations are rapidly determined through the common fault nodes, which makes determination more intuitive, is conducive to the determination of emergency fault at an important moment, and accelerates the scheduling speed of subsequent maintenance.

After the faulty equipment is identified, all downstream power supply paths associated with the faulty equipment are marked as the fault impact scope.

The faulty power supply nodes and the fault impact scope of the faulty paths are shown in the two-dimensional digital scenario; and positions of the faulty equipment are shown in the three-dimensional digital scenario.

The visual display of the scope of influence caused by equipment failure and the specific locations of the faulty equipment provide clear and intuitive guidance for logistics power supply support.

According to the solution of this embodiment, the digital twin scenarios are hierarchically established respectively from the perspective of the macro regional scenario and the specific location scenario, which can macroscopically supervise the power supply relationship of various power supply paths within a region, and also provide targeted information supervision for the network distribution equipment in all the scenarios. The complete power supply path is constructed according to the signal flow relationship between the power topology and the equipment, and power supply path tracing is conducted in the event of equipment failure to determine the scope of influence, so that tracing is fast and accurate. All the power supply paths are traced upstream simultaneously, and the fault locations are rapidly determined through the common fault nodes, which makes determination more intuitive, is conducive to the determination of emergency fault at an important moment, and accelerates the scheduling speed of subsequent maintenance. The visual display of the scope of influence caused by equipment failure and the specific locations of the faulty equipment provide clear and intuitive guidance for logistics power supply support.

### Embodiment II

The embodiment of the present invention also provides a computer-readable storage medium. The computer-readable storage medium includes stored computer programs, and the computer programs control a device where the computer-readable storage medium is located to implement the method for tracing power supply paths in important locations based on digital twins as described in any of the above embodiment during runtime.

A device for tracing power supply paths in important locations based on digital twins includes a processor, a memory, and computer programs which are stored in the memory and can run on the processor. When the processor executes the computer programs, steps of the method for tracing power supply paths in important locations based on digital twins in the embodiment are implemented. Alternatively, when the processor executes the computer programs, functions of all modules/units of the foregoing devices in the embodiment are achieved.

Exemplarily, each of the computer programs may be divided into one or more modules/units, and the one or more modules/units are stored in the memory and executed by the processor to accomplish the present invention. The one or more modules/units may be a series of computer program instruction segments capable of completing specific functions, and the instruction segments are used to describe the execution process of the computer programs in the device for tracing power supply paths in important locations based on digital twins.

The device for tracing power supply paths in important locations based on digital twins may include, but is not limited to, a processor and a memory. Those skilled in the art can understand that the processor and the memory are merely examples for the device for tracing power supply paths in important locations based on digital twins, and do not constitute a limitation to the device for tracing power supply paths in important locations based on digital twins; the device may include more or fewer components, or a combination of some components, or different components; and for example, the device for tracing power supply paths in important locations based on digital twins may further include an input/output device, a network access facility, a bus, and the like.

The processor may be a central processing unit (CPU), or may be another general-purpose processor, a digital signal processor (DSP), an application specific integrated circuit (ASIC), a field-programmable gate array (FPGA), or another programmable logic device (PLD), a discrete gate or transistor logic device, a discrete hardware component, or the like. The general-purpose processor may be a microprocessor, or the processor may also be any regular processor; the processor is a control center of the device for tracing power supply paths in important locations based on digital twins; and various interfaces and lines are used to connect various portions of the entire device for tracing power supply paths based on digital twins.

The memory can be used to store the computer programs and/or modules. The processor realizes various functions of the device for tracing power supply paths in important locations based on digital twins by running or executing the computer programs and/or modules stored in the memory, and calling the data stored in the memory. The memory may mainly include a program storage area and a data storage area, where the program storage area may store an operating system, an application program required by at least one function (such as a sound playback function, and an image playback function), and the like; and the data storage area may store data (such as audio data, and a phone book) created according to the use of a mobile phone, and the like. In addition, the memory may include a high-speed random access memory, and may further include a non-volatile memory, such as a hard disk, a memory, a plug-in hard disk, a smart media card (SMC), a secure digital (SD) card, a flash card, at least one disk storage device, a flash device, or another volatile solid-state storage device.

If being implemented in the form of software functional units and sold or used as independent products, the modules/units integrated in the device for tracing power supply paths in important locations based on digital twins can be stored in a computer-readable storage medium. Based on such understanding, the present invention implements all or part of the processes in the method described in the foregoing embodiments, and may also instruct relevant hardware to complete same by means of computer programs. The computer programs may be stored in a computer-readable storage medium; and when being executed by a processor, the computer programs may implement the steps in the method described in the foregoing embodiments. The computer programs include computer program codes, and the computer program codes may be in a source code form, an object code form, an executable file, or some intermediate form. The computer-readable medium may include any entity or device capable of carrying the computer program codes, a recording medium, a USB flash drive, a removable hard disk, a diskette, a compact disc, a computer memory, a read-only memory (ROM), a random access memory (RAM), an electrical carrier signal, a telecommunication signal, and a software distribution medium.

It should be understood that the embodiments are only used to illustrate the present invention and not intended to limit the scope of the present invention. Furthermore, it should be understood that after reading the content taught in the present invention, those skilled in the art may make various changes or modifications to the present invention, and these equivalent forms shall also fall within the scope as defined in the Claims attached to the present application.

1. A method for tracing power supply paths in important locations based on digital twins, comprising the following steps:
S1: hierarchically establishing, according to actual regional scenarios, a two-dimensional digital twin scenario and a three-dimensional digital twin scenario which correspond to each other;
S2: acquiring equipment information comprising IP addresses uploaded by all network distribution equipment, from control centers in the corresponding areas; and assigning, according to the monitored equipment information, the network distribution equipment to corresponding spatial positions in the two-dimensional digital twin scenario and the three-dimensional digital twin scenario;
S3: connecting, according to an existing topology diagram, all the network distribution equipment to form preliminary power supply paths, controlling the network distribution equipment to send marking commands to upstream network distribution equipment respectively, allowing the network distribution equipment to send feedback on markers to control centers, and optimizing and correcting the preliminary power supply paths, so as to form a plurality of equipment power supply paths; and
S4: when there is an abnormality in the network distribution equipment, tracing according to the power supply path where the network distribution equipment is located, so as to determine a faulty path and faulty equipment.

2. The method for tracing power supply paths in important locations based on digital twins according to claim 1, wherein the two-dimensional digital twin scenario is a two-dimensional regional scenario; and the two-dimensional regional scenario comprises relative positions of various locations within a region, and the corresponding network distribution equipment in various locations; and
the three-dimensional digital twin scenario is a three-dimensional location scenario; and
the three-dimensional location scenario comprises spatial position distribution of the corresponding network distribution equipment in various locations.

3. The method for tracing power supply paths in important locations based on digital twins according to claim 1, wherein the step S2 comprises the following process:
S201: acquiring the equipment information uploaded by the network distribution equipment from control centers in the areas;
S202: assigning, according to IP addresses in the equipment information of the network distribution equipment, the network distribution equipment to corresponding locations in the two-dimensional digital scenario; and
S203: matching, according to equipment types and numbers in the equipment information, the network distribution equipment in various locations with the network distribution equipment in the three-dimensional digital scenario, so as to match the equipment information to corresponding spatial positions.

4. The method for tracing power supply paths in important locations based on digital twins according to claim 1, wherein the step S3 comprises the following process:
S301: acquiring a corresponding network distribution topology diagram within a region from control centers in the areas, and connecting, according to the network distribution topology diagram, all the network distribution equipment in the digital scenarios to obtain the preliminary power supply paths;
S302: acquiring all the terminal network distribution equipment in the preliminary power supply paths, controlling all the network distribution equipment to send the marking commands to the upstream network distribution equipment respectively, and allowing the network distribution equipment to send the feedback on the markers to control centers upon receiving the marking commands;
S303: instructing control centers to collect the feedback on the markers sent by all the network distribution equipment, and forming, according to a content of the feedback on the markers, topological connection relationships between distribution networks; and
S304: comparing the topological connection relationships of the feedback on the markers with the network distribution topology diagram, and optimizing and supplementing the preliminary power supply paths, so as to form the plurality of equipment power supply paths.

5. The method for tracing power supply paths in important locations based on digital twins according to claim 1, wherein various locations in the two-dimensional digital scenario are treated as a node and connected according to a power topology diagram, so as to form a plurality of preliminary power supply paths; and
for each of the locations, each equipment in the scenario is connected according to the power topology diagram to perfect the power supply path.

6. The method for tracing power supply paths in important locations based on digital twins according to claim 1, wherein the marking commands comprise markers whose names contain unique numbers of the terminal network distribution equipment; and an initial value of the marking commands is 0;
after receiving command markers sent by downstream network distribution equipment, the network distribution equipment adds one to the values of the command markers to obtain corresponding feedback on the markers;
the feedback on the markers comprises the markers whose names contain unique numbers of the corresponding terminal network distribution equipment and unique codes of the network distribution equipment that send the command markers; and
the network distribution equipment forms a set of all feedback on the markers, and sends same to control centers.

7. The method for tracing power supply paths in important locations based on digital twins according to claim 3, wherein a transmission method of command markers is as follows:
instructing the terminal network distribution equipment to send the command markers with an initial value of 0 to the upstream network distribution equipment;
for the network distribution equipment that have received the command markers, adding one to the command markers to form feedback on the markers, and transmitting the command markers after adding one to the values to the remaining network distribution equipment connected to the above network distribution equipment, wherein the command markers are not sent to the remaining network distribution equipment; and
transmitting the command markers circularly until there is no object to which the command markers can be transmitted in all the network distribution equipment.

8. The method for tracing power supply paths in important locations based on digital twins according to claim 6, wherein control centers in the areas will be classified according to an expression of the feedback on the markers, and arranged in a descending order of values; and a plurality of groups of topological connection relationships are obtained;
all the topological connection relationships are traversed to determine whether there are same topological connection relationships in the preliminary power supply paths; if so, the corresponding topological connection relationships are removed; and otherwise, a next step of conflict resolution is proceeded; and
whether the topological connection relationships conflict with the existing preliminary power supply paths is determined; if so, the corresponding topological connection relationships are removed; and otherwise, the equipment power supply paths are formed according to the topological connection relationships.

9. The method for tracing power supply paths in important locations based on digital twins according to claim 1, wherein the step S4 comprises the following process:
S401: performing real-time collection and acquisition on the equipment information uploaded by all the network distribution equipment, and comparing index parameters in the equipment information with corresponding threshold values, so as to determine whether the network distribution equipment is abnormal;
S402: when there is the abnormality in the network distribution equipment, tracing upstream according to the equipment power supply path, and determining a faulty power supply node based on statuses of the network distribution equipment at all power supply nodes in the equipment power supply paths; and
S403: determining, according to all the equipment power supply paths associated with the faulty power supply node, a fault impact scope, and locating a spatial position of the faulty equipment to perform a power maintenance operation.

10. The method for tracing power supply paths in important locations based on digital twins according to claim 8, wherein the process of tracing upstream specifically comprises:
1) if there is only one abnormal power supply path in the same time period, the most upstream power supply node, at which the abnormal equipment exists, in the power supply path is determined as a faulty power supply node;
2) if there is more than one abnormal power supply path in the same time period, it is determined whether the same power supply nodes exist in the abnormal power supply paths;
3) whether the abnormal equipment at the same power supply nodes in all the power supply paths are the same is determined; if so, the same abnormal equipment is extracted and determined as the abnormal equipment; and otherwise, each abnormal equipment is checked respectively, and a most upstream abnormal equipment in the power supply path is treated as the faulty equipment.

11. The method for tracing power supply paths in important locations based on digital twins according to claim 10, wherein if there are no same power supply nodes in the abnormal power supply paths, the upstream power supply nodes, at which the abnormal equipment exist, in the power supply paths are determined as the faulty power supply nodes, respectively; and
if there are the same power supply nodes in the abnormal power supply paths, the same power supply nodes in the paths are extracted, and the equipment information of the abnormal equipment at the corresponding power supply nodes is fed back.

12. The method for tracing power supply paths in important locations based on digital twins according to claim 1, wherein the faulty power supply nodes and the fault impact scope of the faulty paths are shown in the two-dimensional digital scenario; and positions of the faulty equipment are shown in the three-dimensional digital scenario.

13. A readable storage medium, characterized in that-wherein the readable storage medium stores one or more programs, and the one or more programs can be executed by one or more processors to implement steps of the method for tracing power supply paths in important locations based on digital twins according to claim 1.

14. A readable storage medium, wherein the readable storage medium stores one or more programs, and the one or more programs can be executed by one or more processors to implement steps of the method for tracing power supply paths in important locations based on digital twins according to claim 2.

15. A readable storage medium, wherein the readable storage medium stores one or more programs, and the one or more programs can be executed by one or more processors to implement steps of the method for tracing power supply paths in important locations based on digital twins according to claim 3.

16. A readable storage medium, wherein the readable storage medium stores one or more programs, and the one or more programs can be executed by one or more processors to implement steps of the method for tracing power supply paths in important locations based on digital twins according to claim 4.

17. A readable storage medium, wherein the readable storage medium stores one or more programs, and the one or more programs can be executed by one or more processors to implement steps of the method for tracing power supply paths in important locations based on digital twins according to claim 5.

18. A readable storage medium, wherein the readable storage medium stores one or more programs, and the one or more programs can be executed by one or more processors to implement steps of the method for tracing power supply paths in important locations based on digital twins according to claim 6.

19. A readable storage medium, wherein the readable storage medium stores one or more programs, and the one or more programs can be executed by one or more processors to implement steps of the method for tracing power supply paths in important locations based on digital twins according to claim 7.

20. A readable storage medium, wherein the readable storage medium stores one or more programs, and the one or more programs can be executed by one or more processors to implement steps of the method for tracing power supply paths in important locations based on digital twins according to claim 8.
